(19) United States
(12) Patent Application Publication
(10) Pub. No.: US 2021/0320136 A1
(43) Pub. Date: Oct. 14, 2021

(54) IMAGE PICKUP APPARATUS AND METHOD FOR MANUFACTURING IMAGE PICKUP APPARATUS

(71) Applicant: OLYMPUS CORPORATION, Tokyo (JP)

(72) Inventor: Kensuke SUGA, Kamiina-gun (JP)

(73) Assignee: OLYMPUS CORPORATION, Tokyo (JP)

(21) Appl. No.: 17/348,266

(22) Filed: Jun. 15, 2021

Related U.S. Application Data
(63) Continuation of application No. PCT/JP2018/046799, filed on Dec. 19, 2018.

(51) Int. Cl. H01L 27/146

(52) U.S. Cl. CPC H01L 27/14618; H01L 27/14634; H01L 27/14625

(57) ABSTRACT

An image pickup apparatus includes a cover glass including a first principal surface and a second principal surface, an image pickup member which includes a light receiving surface and a rear surface and in which the light receiving surface is disposed on the second principal surface which is larger than the light receiving surface, and a first resin disposed around the image pickup member of the second principal surface, having the same external size of a cross-section orthogonal to an optical axis as an external size of a cross-section of the second principal surface, and including a trench parallel to the optical axis on a side surface, and a second resin disposed in the trench.

### CROSS REFERENCE TO RELATED APPLICATION

This application is a continuation application of PCT/JP2018/046799 filed on Dec. 19, 2018, the entire contents of which are incorporated herein by this reference.

### BACKGROUND OF THE INVENTION

### 1. Field of the Invention

The present invention relates to an image pickup apparatus including an image pickup member in which a transparent plate is disposed on a light receiving surface, and a method for manufacturing an image pickup apparatus including an image pickup member in which a transparent plate is disposed on a light receiving surface.

### 2. Description of the Related Art

A cover glass is bonded to an image pickup device of an image pickup apparatus to protect a light receiving surface.

An image pickup apparatus disclosed in International Publication No. 2018/087872 includes a cover glass and an image pickup device which have the same external size of cross-sections orthogonal to an optical axis. The above-described image pickup apparatus is manufactured through a process of cutting a bonded wafer in which a glass wafer is bonded to an image pickup wafer including a plurality of image pickup devices.

### SUMMARY OF THE INVENTION

An image pickup apparatus of an embodiment includes a transparent plate including a first principal surface and a second principal surface on an opposite side of the first principal surface, an image pickup member which includes a light receiving surface and a rear surface on an opposite side of the light receiving surface, and in which the light receiving surface is disposed on the second principal surface which is larger than the light receiving surface, a first resin disposed around the image pickup member, having the same external size of a cross-section orthogonal to an optical axis as an external size of a cross-section of the second principal surface, and including at least one trench parallel to the optical axis on at least one side surface, and a second resin disposed in the trench.

A method for manufacturing an image pickup apparatus of an embodiment includes disposing light receiving surfaces of a plurality of image pickup members including the light receiving surfaces and rear surfaces on an opposite side of the light receiving surfaces on a second principal surface of a transparent wafer including a first principal surface and the second principal surface on an opposite side of the first principal surface in a state where space is provided between the image pickup members, disposing a first resin in the space around the plurality of image pickup members, forming at least one hole in the first resin, separating the wafer into stacked bodies which include a trench parallel to an optical axis on at least one side surface by cutting the wafer on a cut line which crosses the hole, and disposing a second resin in the trench.

### BRIEF DESCRIPTION OF THE DRAWINGS

FIG. 1 is a perspective view of an image pickup apparatus of a first embodiment;

FIG. 2 is a cross-sectional diagram along a line II-II in FIG. 1 of the image pickup apparatus of the first embodiment;

FIG. 3 is an exploded view of the image pickup apparatus of the first embodiment;

FIG. 4 is a flowchart for explaining a method for manufacturing the image pickup apparatus of the first embodiment;

FIG. 5 is a cross-sectional diagram for explaining the method for manufacturing the image pickup apparatus of the first embodiment;

FIG. 6 is a cross-sectional diagram for explaining the method for manufacturing the image pickup apparatus of the first embodiment;

FIG. 7 is a cross-sectional diagram along a line VII-VII in FIG. 8 for explaining the method for manufacturing the image pickup apparatus of the first embodiment;

FIG. 8 is a top view for explaining the method for manufacturing the image pickup apparatus of the first embodiment;

FIG. 9 is a cross-sectional diagram for explaining the method for manufacturing the image pickup apparatus of the first embodiment;

FIG. 10 is a cross-sectional diagram for explaining the method for manufacturing the image pickup apparatus of the first embodiment;

FIG. 11 is a perspective view of a stacked body of the image pickup apparatus of the first embodiment;

FIG. 12 is an exploded view for explaining the method for manufacturing the image pickup apparatus of the first embodiment;

FIG. 13 is a perspective view of a stacked body of an image pickup apparatus in a modification of the first embodiment;

FIG. 14 is a top view for explaining a method for manufacturing the image pickup apparatus in the modification of the first embodiment; and

FIG. 15 is an exploded view of an image pickup apparatus of a second embodiment.

### DETAILED DESCRIPTION OF THE PREFERRED EMBODIMENTS

### First Embodiment

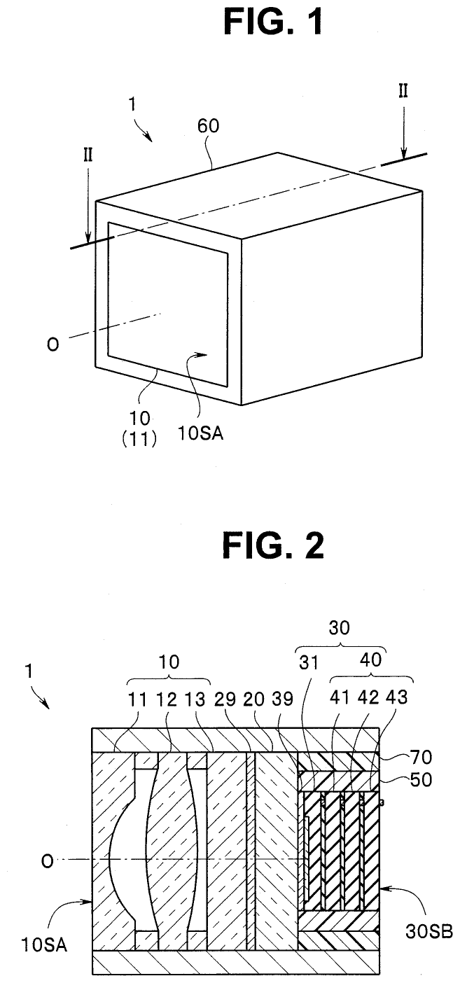

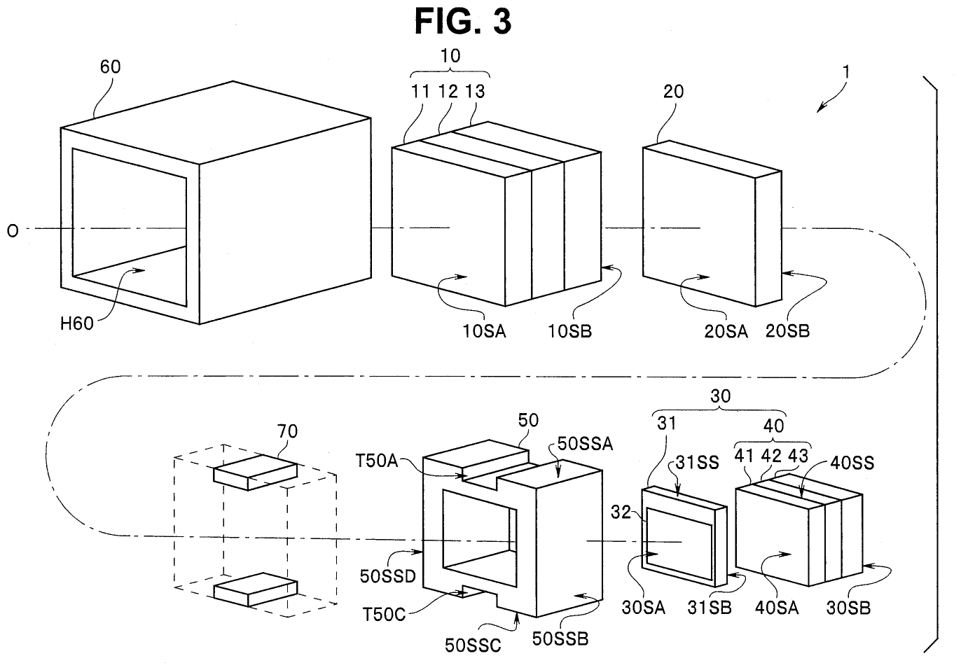

As illustrated in FIG. 1, FIG. 2 and FIG. 3, an image pickup apparatus 1 of a first embodiment includes an optical member 10, a cover glass 20 which is a transparent plate, an image pickup member 30, a first resin 50, a second resin 70 and a frame 60.

Note that the drawings are schematic, and relationships between a thickness and a width of each member, ratios of respective members, or the like, are different from actual relationships, ratios, or the like. Some dimensions and ratios may differ between the drawings. Illustration of some components and illustration of some reference numerals may be omitted. Further, a direction toward an object will be referred to as a “front” direction.

The cover glass 20 includes a first principal surface 20SA and a second principal surface 20SB on an opposite side of the first principal surface 20SA. The transparent plate may be a resin plate formed with polycarbonate, or the like.

The image pickup member 30 includes an image pickup device 31 and a stacked device 40, and includes a light receiving surface 30SA and a rear surface 30SB on an opposite side of the light receiving surface 30SA.

The image pickup device (imager chip) 31 includes the light receiving surface 30SA, a back surface 31SB on an opposite side of the light receiving surface 30SA, and four side surfaces 31SS. The image pickup device 31 includes a light receiving portion 32 on the light receiving surface 30SA. A plurality of external electrodes connected to the light receiving portion 32 are disposed on the back surface 31SB.

The stacked device 40 includes a front surface 40SA, the rear surface 30SB on an opposite side of the front surface 40SA, and four side surfaces 40SS, and the front surface 40SA is disposed on the back surface 31SB of the image pickup device 31. Note that the stacked device 40 is not an essential component of the image pickup member 30. In other words, the image pickup member 30 may be the image pickup device 31 to which the cover glass 20 is bonded. Further, in the image pickup member 30, a protective glass is bonded to the light receiving surface 30SA of the image pickup device 31, and the cover glass 20 may be further bonded to the protective glass.

The light receiving surface 30SA of the image pickup member 30 (image pickup device 31) is bonded to the second principal surface 20SB of the cover glass 20 having an external size orthogonal to the optical axis O larger than an external size of the light receiving surface 30SA using a transparent adhesive agent 39. In other words, a peripheral portion of the second principal surface 20SB includes a frame-like region in which the image pickup member 30 is not disposed, which generates a difference in level at a boundary of the side surfaces of the cover glass 20 and the side surfaces of the image pickup member 30.

The optical member 10 includes a third principal surface 10SA and a fourth principal surface 10SB on an opposite side of the third principal surface 10SA, and the fourth principal surface 10SB is disposed on the first principal surface 20SA of the cover glass 20. The optical member 10 in which a plurality of optical devices 11, 12 and 13 are stacked forms an object image on the light receiving surface 30SA of the image pickup device 31.

The optical device 11 is a plano-concave lens. The optical device 12 is a convex lens. The optical device 13 is a filter. The optical member 10 may include other optical devices such as an aperture, and types, the number, or the like, of the optical devices of the optical member 10 are designed in accordance with specifications.

The first resin 50 is disposed around the image pickup member 30 of the second principal surface 20SB of the cover glass 20 and covers the four side surfaces (31SS, 40SS) of the image pickup member 30. The first resin 50 has the same external size of a cross-section orthogonal to the optical axis O as an external size of a cross-section of the second principal surface 20SB.

In the image pickup apparatus 1, a difference in level at the boundary of the side surfaces of the cover glass 20 and the side surfaces of the image pickup member 30 is covered with the first resin 50 disposed on the second principal surface 20SB. In the image pickup apparatus 1, stress does not concentrate at the boundary of the cover glass 20 and the image pickup member 30, and thus, reliability does not degrade due to detachment of an adhesive surface.

Particularly, in a case where the image pickup apparatus 1 is an image pickup apparatus for endoscope which is disposed at a distal end portion of an insertion portion of a flexible endoscope, if the insertion portion deforms, stress is applied to the image pickup apparatus 1 by way of a signal cable connected to the image pickup member 30. However, in the image pickup apparatus 1, there is no difference in dimension between the optical member 10 and the image pickup member 30, and the optical member 10 and the image pickup member 30 have the same area of cross-sections in a direction orthogonal to the optical axis, and thus, high reliability with respect to stress can be achieved.

Note that in the image pickup apparatus 1, the cover glass 20 and the image pickup member 30 are protected by being accommodated in the frame 60. However, the image pickup member 30 is covered with the first resin 50 even before insertion into the frame 60, so that breakage of the image pickup apparatus 1 during manufacturing is prevented.

Further, the first resin 50 includes trenches T50A and T50C parallel to the optical axis O on two parallel side surfaces 50SSA and 50SSC among four side surfaces 50SS (50SSA, 50SSB, 50SSC, 50SSD). The second resin 70 is disposed in the trenches T50A and T50C.

The frame 60 is a lens frame having space H60 in which the optical member 10 is accommodated. The second resin 70 is an adhesive agent which fixes the first resin 50 in the space H60 of the frame 60.

The external size of the first resin 50 is slightly smaller than an internal size of the space H60 of the frame 60 to which the first resin 50 is inserted. If the stacked body 35 including the optical member 10, the cover glass 20, and the image pickup member 30, side surfaces of which are covered with the first resin 50 is inserted into the space H60 of the frame 60, positional relationship of the optical member 10 and the image pickup member 30 covered with the first resin 50 with respect to the frame 60 in a direction orthogonal to the optical axis is uniquely defined. Thus, also in a case where the frame 60 of the image pickup apparatus 1 is further disposed at other members, positions, that is, rotational angles of the optical member 10 and the image pickup member 30 in the direction orthogonal to the optical axis, are defined.

Further, the first resin 50 is firmly fixed in the frame 60 by the second resin 70 disposed in the trenches T50A and T50C. Thus, high bonding reliability can be achieved between the image pickup member 30 covered with the first resin 50 and the frame 60.

### <Method for Manufacturing Image Pickup Apparatus>

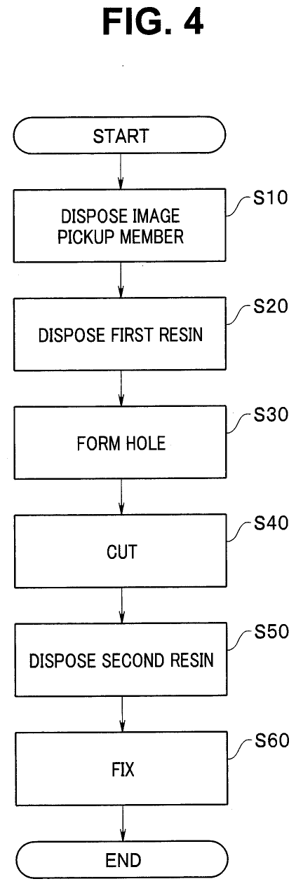

A method for manufacturing the image pickup apparatus will be described along a flowchart illustrated in FIG. 4.

### <Step S10>Process of Disposing Image Pickup Member

The image pickup device 31 is a CMOS image sensor, a CCD, or the like. The image pickup device 31 is manufactured by cutting a silicon wafer, or the like, on which a plurality of light receiving portions 32, or the like, are disposed using a publicly known semiconductor manufacturing technology. A peripheral circuit which performs primary processing on output signals of the light receiving portions 32 or which processes a drive control signal may be formed on the image pickup device wafer including the plurality of light receiving portions 32. The image pickup device 31 may be either a surface irradiation type image sensor or a backside irradiation type image sensor.

The stacked device 40 in which a plurality of semiconductor devices 41, 42 and 43 are stacked performs primary processing on an image pickup signal outputted from the image pickup device 31 or processes a control signal which controls the image pickup device 31. The stacked device 40 is manufactured by cutting a stacked wafer in which a plurality of semiconductor wafers respectively including a plurality of semiconductor devices 41, 42 and 43 are stacked.

For example, the semiconductor devices 41, 42 and 43 include an AD conversion circuit, a memory, a transmission output circuit, a filter circuit, a thin film capacitor, a thin film resistor, and a thin film inductor. The stacked device 40 includes, for example, equal to or more than two and equal to or less than ten devices.

The front surface 40SA of the stacked device 40 is disposed on the back surface 31SB of the image pickup device 31, and the image pickup device 31 is electrically connected to the stacked device 40. Note that an image pickup wafer including a plurality of image pickup devices 31 may be disposed on the stacked wafer in which a plurality of semiconductor wafers including a plurality of semiconductor devices 41, 42 and 43 are stacked, and then may be cut.

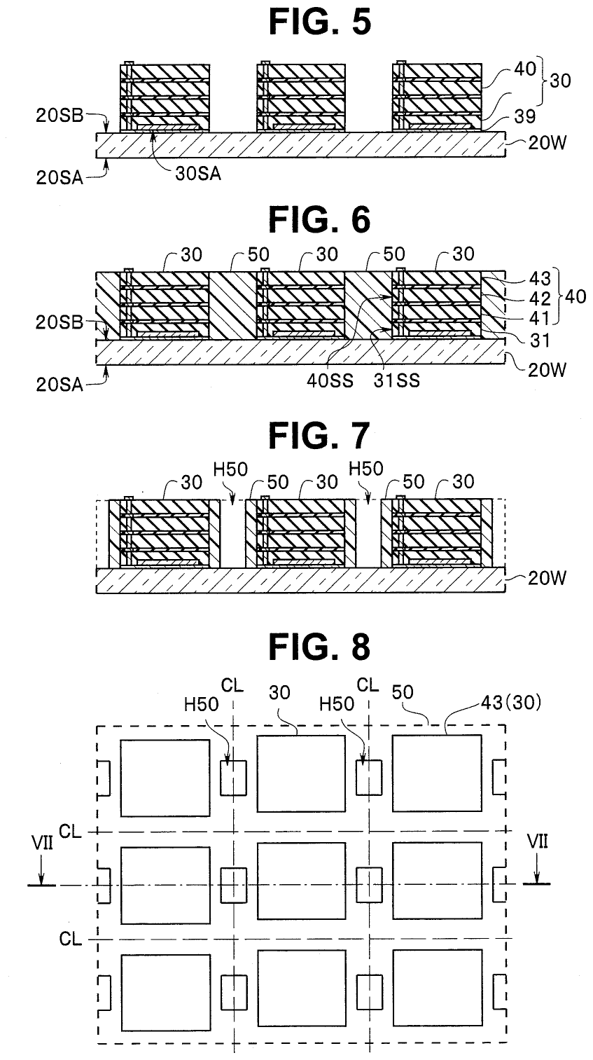

As illustrated in FIG. 5, the light receiving surfaces 30SA of the plurality of image pickup members 30 are disposed on the second principal surface 20SB of a transparent wafer 20W which includes the first principal surface 20SA and the second principal surface 20SB on an opposite side of the first principal surface 20SA using the transparent adhesive agent 39 in a state where space is provided between the image pickup members 30. The transparent wafer 20W becomes the cover glass 20 by being cut in a cutting process S40. The transparent adhesive agent 39 is an ultraviolet curable resin, a thermoset resin or a thermoplastic resin.

### <Step S20>Process of Disposing First Resin

As illustrated in FIG. 6, the first resin 50 is disposed in space around the plurality of image pickup members 30 on the second principal surface 20SB of the transparent wafer 20W. The first resin 50 is an epoxy resin, an acrylic resin, a styrene resin, or the like. The first resin 50 is preferably a light blocking resin including, for example, carbon particles.

The first resin 50 does not have to cover the entire surface of the side surfaces of the image pickup member 30 if the first resin 50 covers part of side surfaces of the semiconductor device 43 disposed at the rearmost position of the stacked device 40.

Note that in the process of disposing the image pickup member S10, only the image pickup device 31 may be bonded to the transparent wafer 20W using the transparent adhesive agent 39. Then, in the process of disposing the first resin S20, after the first resin 50 is disposed so as to cover the side surfaces 31SS of the image pickup device 31, the stacked device 40 may be bonded to the image pickup device 31, and the first resin 50 may cover the side surfaces 40SS of the stacked device 40.

In other words, in place of the process of disposing the image pickup member S10 and the process of disposing the first resin S20, a process of disposing the image pickup device, a process of disposing the first resin 1, a process of disposing the stacked device, and a process of disposing the first resin 2 may be provided.

### <Step S30>Process of Forming Hole

As illustrated in FIG. 7 and FIG. 8, a plurality of holes H50 are formed on the first resin 50 through, for example, laser processing or machine processing. In a case where the first resin 50 is a photoresist resin, the holes H50 are formed through exposure processing and development processing.

The holes H50 pass through the first resin 50, and thus, have bottom surfaces on the second principal surface 20SB of the transparent wafer 20W which becomes the cover glass 20. Note that the holes H50 may be formed to reach inside the cover glass 20 or, conversely, the holes H50 do not have to pass through the first resin 50.

As illustrated in FIG. 8, in the image pickup apparatus 1, the holes H50 are respectively formed in two regions on both sides of the image pickup member 30.

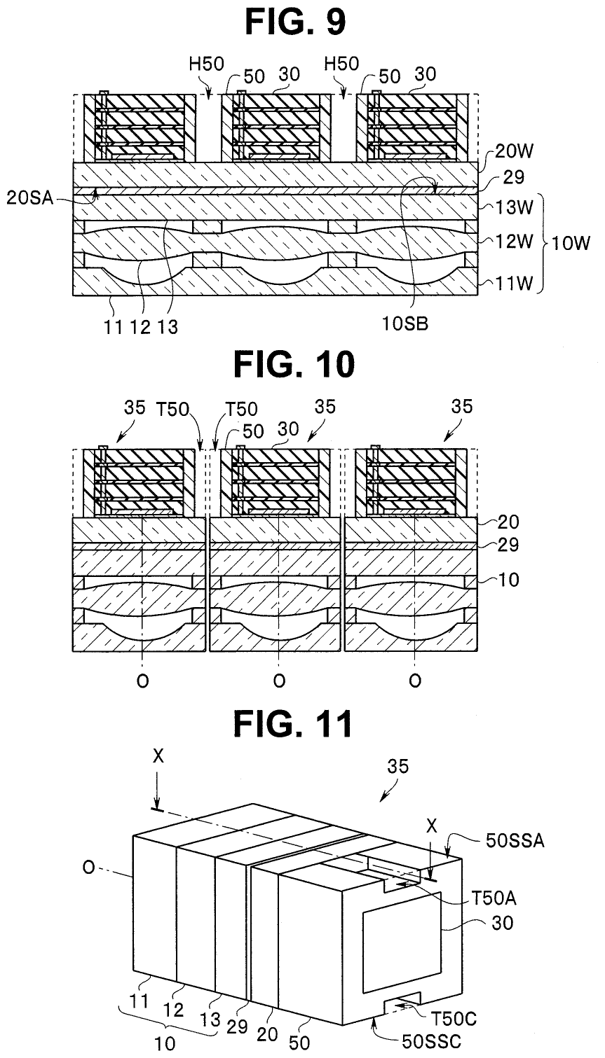

As illustrated in FIG. 9, a fourth principal surface 10SB of an optical stacked wafer 10W in which optical wafers 11W, 12W and 13W respectively including a plurality of optical devices 11, 12 and 13 are stacked is disposed on the first principal surface 20SA of the transparent wafer 20W using a transparent adhesive agent 29.

In other words, a process of disposing an optical member is performed so that the fourth principal surface 10SB of the optical stacked wafer 10W including a third principal surface 10SA and a fourth principal surface 10SB on an opposite side of the third principal surface 10SA is disposed on the first principal surface 20SA of the transparent wafer 20W. The process of disposing the optical member may be performed before step S10 or performed between step S10 and step S20 or between step S20 and step S40.

However, it goes without saying that a manufacturing method in which the transparent wafer 20W to which the optical stacked wafer 10W is bonded is cut is easier than a method in which the optical member 10 is disposed on the transparent wafer 20W or the stacked body 35 as the method for manufacturing the stacked body 35.

### <Step S40>Cutting Process

As illustrated in FIG. 10 and FIG. 11, when the transparent wafer 20W is cut along a cut line CL (see FIG. 8) which crosses the holes H50, the transparent wafer 20W is separated into a plurality of stacked bodies 35. The stacked body 35 including the optical member 10, the cover glass 20, and the image pickup member 30, side surfaces of which are covered with the first resin 50, includes trenches T50A and T50C parallel to the optical axis O respectively on two parallel side surfaces 50SSA and 50SSC.

In other words, the holes H50 of the first resin 50 become trenches T50 of the two stacked bodies 35.

The stacked body 35 has the same external size of a cross-section orthogonal to the optical axis O of the first resin 50 as external sizes of the first principal surface 20SA and the second principal surface 20SB of the cover glass 20.

Further, in the method for manufacturing the image pickup apparatus 1 in which the optical stacked wafer 10W is bonded to the transparent wafer 20W, the stacked body 35 has the same external sizes of the third principal surface 10SA and the fourth principal surface 10SB of the optical member 10, and the first principal surface 20SA and the second principal surface 20SB of the cover glass 20, and a cross-section orthogonal to the optical axis O of the first resin 50.

The side surfaces of the optical member 10 and the side surfaces of the cover glass 20 have the same cross-sectional surface, and no difference in level is provided at a boundary of the optical member 10 and the cover glass 20. Thus, the image pickup apparatus 1 can achieve high mechanical strength and high reliability.

Note that a plurality of optical members 10 manufactured by cutting the optical stacked wafer 10W may be disposed on the transparent wafer 20W. Further, after the cutting process S40, the optical member 10 may be disposed on the stacked body 35. In other words, the process of disposing the optical member may be a process of disposing the fourth principal surface 10SB of the optical member 10 which includes the third principal surface 10SA and the fourth principal surface 10SB on an opposite side of the third principal surface 10SA, on the transparent wafer 20W or the first principal surface 20SA of the cover glass 20.

However, a manufacturing method in which the transparent wafer 20W to which the optical stacked wafer 10W is bonded is cut is easier than a method in which the optical member 10 is disposed on the transparent wafer 20W or the stacked body 35 as the method for manufacturing the stacked body 35.

### <Step S50>Process of Disposing Second Resin

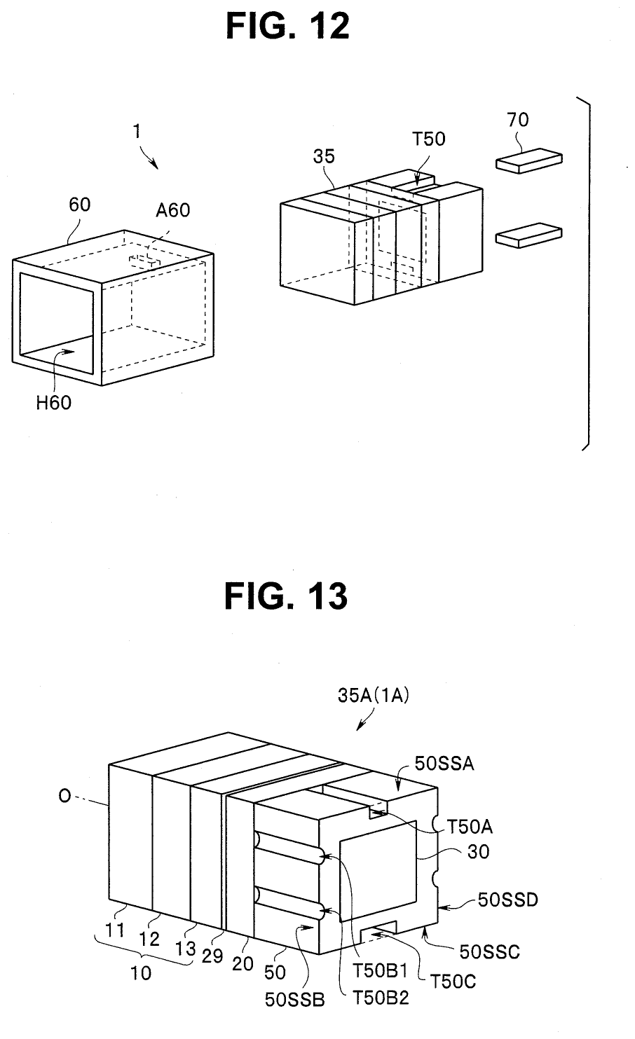

As illustrated in FIG. 12, the stacked body 35 in which the second resin 70 which is an adhesive agent is disposed in the trench T50 is inserted into the frame 60 and fixed. The process of disposing the second resin S50 is a fixing process of inserting the stacked body 35 into the frame 60 and fixing the first resin 50 in the frame 60 using the second resin 70 which is an adhesive agent. The second resin 70 may be injected to a gap after the stacked body 35 is inserted into the frame 60.

The holes H50 of the first resin 50 becomes the trenches T50 of the stacked body 35, and thus, long trenches T50 which are parallel to the optical axis O are easily formed. Thus, according to the manufacturing method of the present embodiment, it is possible to easily manufacture the image pickup apparatus 1.

Note that convexities A60 which engage with the trenches T50 may be provided on an inner surface of the space H60 of the frame 60. The stacked body 35 is easily inserted into the space H60 by using the convexities A60 as insertion guides.

Further, the optical member 10 is not limited to a wafer level optical system manufactured by cutting the optical stacked wafer 10W. The optical member 10 may be, for example, a single-layer optical device instead of a body in which a plurality of optical devices are stacked. In a case where the optical member 10 is not a wafer level optical system, the stacked body 35 is formed with the cover glass 20 and the image pickup member 30, side surfaces of which are covered with the first resin 50.

### Modification of First Embodiment

An image pickup apparatus 1A and a method for manufacturing the image pickup apparatus 1A in a modification of the first embodiment are similar to the image pickup apparatus 1 and the method for manufacturing the image pickup apparatus 1 and provide the same effects, and thus, the same reference numerals will be assigned to the same components, and description will be omitted.

As illustrated in FIG. 13, in a stacked body 35A of the image pickup apparatus 1A, trenches T50A and T50C on parallel side surfaces 50SSA and 50SSC have different widths.

For example, the stacked body 35 has a small cross-section of 1 mm square in a direction orthogonal to the optical axis and has a substantially square cross-section. Thus, it is not easy to distinguish between a state where the stacked body 35 is rotated around the optical axis O by 90 degrees or 180 degrees and a state before the stacked body 35 is rotated and insert the stacked body 35 into the frame 60 in a correct rotated state.

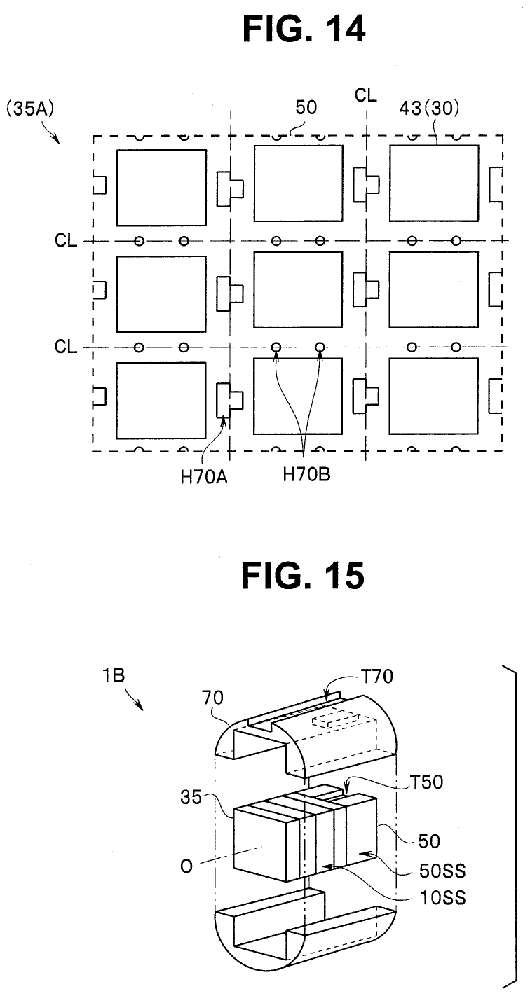

As illustrated in FIG. 14, holes H70A formed in the first resin 50 disposed around the stacked body 35A (image pickup member 30) have different sizes across the cut line CL. Further, holes H70B are also formed in the first resin 50.

The image pickup apparatus 1A can be manufactured more easily than the image pickup apparatus 1 because the rotated state can be easily distinguished by a difference in width of the trenches T50A and T50C of the stacked body 35A, formed by cutting the holes H70A.

Note that at the stacked body 35A, two trenches T50B1 and T50B2 are formed on a side surface 50S SB of the first resin 50 by cutting the holes H70B. Further, two trenches are also formed on a side surface 50SSD which is parallel to the side surface 50SSB by cutting the holes H70B.

In other words, the trenches T50 may be formed on four side surfaces 50SS of the first resin 50 or a plurality of trenches T50 may be formed on one side surface. Conversely, the trenches T50 may be formed on only one of the four side surfaces 50SS of the first resin 50. In other words, it is only necessary that at least one trench T50 should be provided on at least one side surface 50SS of the first resin 50.

### Second Embodiment

An image pickup apparatus 1B and a method for manufacturing the image pickup apparatus 1B of a second embodiment are similar to the image pickup apparatus 1 and the method for manufacturing the image pickup apparatus 1 and provide the same effects, and thus, the same reference numerals will be assigned to the same components, and description will be omitted.

In the image pickup apparatus 1B illustrated in FIG. 15, the second resin 70 is a mold resin which covers four side surfaces 50SS of the first resin 50 and four side surfaces of the optical member 10.

In the method for manufacturing the image pickup apparatus 1B, a process of disposing the second resin S50 is a mold process of molding the second resin 70 so as to cover the four side surfaces of the first resin 50.

The second resin 70 fills the trenches T50 of the first resin 50, so that high reliability of bonding with the first resin 50 can be achieved. Further, the first resin 50 and the optical member 10 are protected by the second resin 70, so that high mechanical strength can be achieved. Thus, the image pickup apparatus 1B achieves high reliability.

Note that if the second resin 70 covers at least four side surfaces 50SS of the first resin 50, the image pickup member 30 of the image pickup apparatus 1B is protected.

Further, in the image pickup apparatus 1B, a trench T70 which is parallel to the optical axis O is provided at the second resin 70. The trench T70 is not an essential component of the image pickup apparatus 1B, and, for example, in a case where the image pickup apparatus 1B is fixed in a state where the image pickup apparatus 1B is inserted into space of the frame, the trench T70 provides the same effects as the effects of the trenches T50.

The image pickup apparatus in which the image pickup member 30 includes the stacked device 40 in which a plurality of semiconductor devices 41 to 43 are stacked and the optical member 10 in which a plurality of optical devices 11 to 13 are stacked has been described above.

The image pickup apparatus including the stacked device 40 achieves high performance because an image pickup signal outputted from the image pickup device 31 is transmitted after the image pickup signal is subjected to primary processing. Further, it is not necessary to provide a process of incorporating separate optical members at the image pickup apparatus including the optical member 10, so that it is possible to easily make the image pickup apparatus smaller

However, it goes without saying that the image pickup apparatus of the embodiments provide the effects described above even if the image pickup member 30 is the image pickup device 31, and the image pickup member 30 does not include the optical member 10.

The present invention is not limited to the embodiments and the modification described above, and various changes, modifications, or the like, are possible within a range not deviating from the gist of the present invention.

What is claimed is:

1. An image pickup apparatus comprising:
a transparent plate including a first principal surface and a second principal surface on an opposite side of the first principal surface;
an image pickup member which includes a light receiving surface and a rear surface on an opposite side of the light receiving surface, and in which the light receiving surface is disposed on the second principal surface which is larger than the light receiving surface;
a first resin disposed around the image pickup member, having a same external size of a cross-section orthogonal to an optical axis as an external size of a cross-section of the second principal surface, and including at least one trench parallel to the optical axis on at least one side surface; and
a second resin disposed in the trench.

2. The image pickup apparatus according to claim 1,
wherein the image pickup member includes an image pickup device and a stacked device,
the image pickup device includes the light receiving surface and a back surface on an opposite side of the light receiving surface, and
the stacked device includes the rear surface and a front surface on an opposite side of the rear surface, the front surface is disposed on the back surface, and a plurality of semiconductor devices are stacked.

3. The image pickup apparatus according to claim 2, further comprising:
an optical member which includes a third principal surface and a fourth principal surface on an opposite side of the third principal surface, and in which the fourth principal surface is disposed on the first principal surface, and a plurality of optical devices are stacked.

4. The image pickup apparatus according to claim 3,
wherein the fourth principal surface has a same external size as an external size of the first principal surface.

5. The image pickup apparatus according to claim 1,
wherein the first resin includes the trench on each of two parallel side surfaces.

6. The image pickup apparatus according to claim 5,
wherein the trench on each of the two side surfaces has a different width.

7. The image pickup apparatus according to claim 1, further comprising:
a frame in which the first resin is accommodated,
wherein the second resin is an adhesive agent which fixes the first resin in the frame.

8. The image pickup apparatus according to claim 1,
wherein the second resin is a mold resin which covers four side surfaces of the first resin.

9. A method for manufacturing an image pickup apparatus comprising:
disposing light receiving surfaces of a plurality of image pickup members including the light receiving surfaces and rear surfaces on an opposite side of the light receiving surfaces on a second principal surface of a transparent wafer including a first principal surface and the second principal surface on an opposite side of the first principal surface in a state where space is provided between the image pickup members;
disposing a first resin in the space around the plurality of image pickup members;
forming at least one hole in the first resin;
separating the wafer into stacked bodies which include a trench parallel to an optical axis on at least one side surface by cutting the wafer on a cut line which crosses the hole; and
disposing a second resin in the trench.

10. The method for manufacturing the image pickup apparatus according to claim 9,
wherein each of the image pickup members includes an image pickup device and a stacked device, and
the image pickup device includes each of the light receiving surfaces and a back surface on an opposite side of each of the light receiving surfaces, the stacked device includes the rear surface and a front surface on an opposite side of the rear surface, the front surface is disposed on the back surface, and a plurality of semiconductor devices are stacked.

11. The method for manufacturing the image pickup apparatus according to claim 9,
wherein a fourth principal surface of an optical member which includes a third principal surface and the fourth principal surface on an opposite side of the third principal surface and in which a plurality of optical devices are stacked is disposed on the first principal surface of the transparent wafer.

12. The method for manufacturing the image pickup apparatus according to claim 9,
wherein when the hole is formed, the hole is formed in each of two regions on both sides of the image pickup member.

13. The method for manufacturing the image pickup apparatus according to claim 10,
wherein when the second resin is disposed, the stacked body is inserted into a frame, and the first resin is fixed in the frame with the second resin which is an adhesive agent.

14. The method for manufacturing the image pickup apparatus according to claim 10,
wherein when the second resin is disposed, the second resin is molded so as to cover four side surfaces of the first resin.
